(19) United States
(12) Patent Application Publication
(10) Pub. No.: US 2014/0139319 A1
(43) Pub. Date: May 22, 2014

(54) Remotely Readable Input Forms

(71) Applicant: TRIMBLE NAVIGATION LIMITED, Sunnyvale, CA (US)

(72) Inventor: Edward Jones, Palo Alto, CA (US)

(73) Assignee: Trimble Navigation Limited, Sunnyvale, CA (US)

(21) Appl. No.: 13/679,157

(22) Filed: Nov. 16, 2012

(51) Int. Cl. G06K 19/077; H05K 3/12; H05K 3/30

(52) U.S. Cl. CPC G06K 19/07749; H05K 3/30; H05K 3/12
USPC 340/10.1; 235/492; 29/846

(57) ABSTRACT

A system for obtaining electronic data from a plurality of forms includes a plurality of electronic sensors, a plurality of wireless interface circuits, and at least one reader configured to communicate with the wireless interface circuits to obtain the electronic data from the plurality of forms. At least one electronic sensor may be coupled to each form, and each electronic sensor may be configured to sense at least a first state and a second state based on manipulation of the form to which the electronic sensor is coupled. At least one of the wireless interface circuits may be coupled to each form and to the at least one electronic sensor coupled to the form. For each form the electronic data may include at least one state of the at least one electronic sensor coupled to the form.

### TECHNICAL FIELD

Embodiments of the present invention relate generally to input forms that are configured to provide electronic data that is remotely readable. In an embodiment, the electronic data is remotely readable via a wireless interface circuit (e.g., a radio frequency identification (RFID) tag circuit). Some embodiments also include methods and systems relating to forming and using the input forms.

### BACKGROUND

Punch cards have been used for many years as a means of storing and conveying digital information. The information is generated by creating holes in predefined positions on the card. A reader interprets the information based on the positions of the holes.

Bubble sheets or optical answer sheets are often used for examinations and operate on a similar principle. Information is generated by filling in blank ovals on the sheet using a pencil or pen. An electronic reader interprets the information based on those ovals that are filled.

While these and similar technologies provide established methods for storing and conveying digital information using forms, improved methods and systems are constantly desired for making digital information easier to generate and more efficient to read.

### SUMMARY

Some embodiments of the present invention provide improved means for generating and reading digital information using input forms. The digital information may be referred to as electronic data. This is because the information can be electronically communicated directly to a reader and can be accessed remotely. This is in contrast to punch cards, bubble sheets, and other similar technologies where physical inspection by a reader is required to interpret the information.

In accordance with an embodiment of the invention, a system for obtaining electronic data from a plurality of forms includes a plurality of electronic sensors, where at least one electronic sensor is coupled to each form. Each electronic sensor may be configured to sense at least a first state and a second state based on manipulation of the form to which the electronic sensor is coupled. The system also includes a plurality of RFID tag circuits, where at least one of the RFID tag circuits is coupled to each form and to the at least one electronic sensor coupled to the form. The system also includes an RFID reader configured to communicate with the plurality of RFID tag circuits to obtain the electronic data from the plurality of forms. For each form the electronic data includes at least one state of the at least one electronic sensor coupled to the form.

In an embodiment, the plurality of electronic sensors are printed electronic sensors comprising a conductive ink. In another embodiment, the plurality of RFID tag circuits are printed RFID tag circuits comprising a conductive ink.

In one embodiment, at least one of the plurality of forms comprises paper. In another embodiment, at least one of the plurality of forms comprises plastic.

In another embodiment, at least a portion of the RFID tag circuits are active RFID tag circuits that include a memory. Each active RFID tag circuit may be configured to store in the memory changes between the first state and the second state sensed by the at least one electronic sensor.

In yet another embodiment, at least a portion of the RFID tag circuits are passive RFID tag circuits. The RFID reader may be configured to interrogate the passive RFID tag circuits using radio frequency (RF) signals to obtain the electronic data.

In accordance with another embodiment of the invention, a form for providing electronic data includes a substrate, a wireless interface circuit coupled to the substrate, and at least one electronic sensor coupled to the substrate and to the wireless interface circuit. The electronic sensor may be configured to sense at least a first state and a second state based on manipulation of the substrate or manipulation of the electronic sensor. The wireless interface circuit may be configured to provide the electronic data including at least one state of the electronic sensor to a reader.

In an embodiment, the wireless interface circuit includes an RFID tag circuit. In another embodiment, the wireless interface circuit is based on at least one of an ISO/IEC/IEEE 8802-11, ISO/IEC/IEEE 8802-15, or IEEE 802 standard.

In one embodiment, the at least one electronic sensor comprises an electronic circuit that is bonded to the substrate. In another embodiment, the wireless interface circuit comprises an electronic circuit that is bonded to the substrate.

In accordance with yet another embodiment of the invention, a method for forming a form that is configured to provide electronic data includes providing a substrate, forming an RFID tag circuit on the substrate, and forming an electronic sensor on the substrate. The electronic sensor may be coupled to the RFID tag circuit and configured to sense at least a first state and a second state based on manipulation of the substrate. The RFID tag circuit may be configured to provide the electronic data including a state of the electronic sensor to an RFID reader.

These and other embodiments, along with many advantages and features, are described in more detail below in conjunction with the figures.

### BRIEF DESCRIPTION OF THE DRAWINGS

FIGS. 1a-1b are simplified diagrams of input forms that may be used to obtain electronic data in accordance with some embodiments of the invention;

FIG. 2 is a simplified diagram of a system that may be used to obtain electronic data in accordance with an embodiment of the invention;

FIGS. 3a-3b are simplified diagrams of input forms that may be used to obtain electronic data in accordance with other embodiments of the invention; and

FIG. 4 is a flowchart of a method for forming an input form that is configured to provide electronic data in accordance with an embodiment of the invention.

### DETAILED DESCRIPTION

Some embodiments of the present invention provide improved methods for generating and obtaining electronic data using input forms. In accordance with an embodiment, for example, an input form may include an electronic sensor coupled with a wireless interface circuit such as an RFID tag circuit. The electronic sensor may be configured to sense a particular state of a circuit (e.g., a short, open, etc.), where the state can be changed based on manipulation of the input form (e.g., from closed to open, open to closed, etc.). The RFID tag circuit may be configured to receive the state from the electronic sensor (or determine the state of the electronic sensor) and provide the state to a reader.

In a particular embodiment, the electronic sensor and the RFID tag circuit may be formed as printed electronic circuits on a sheet of paper. The electronic sensor may sense a particular state based on manipulation of the input form (e.g., filling in a bubble or box, checking a box, punching a hole in a particular position, tearing the form at a particular position, and the like). The RFID tag circuit may provide the state of the electronic sensor to a reader either actively or passively.

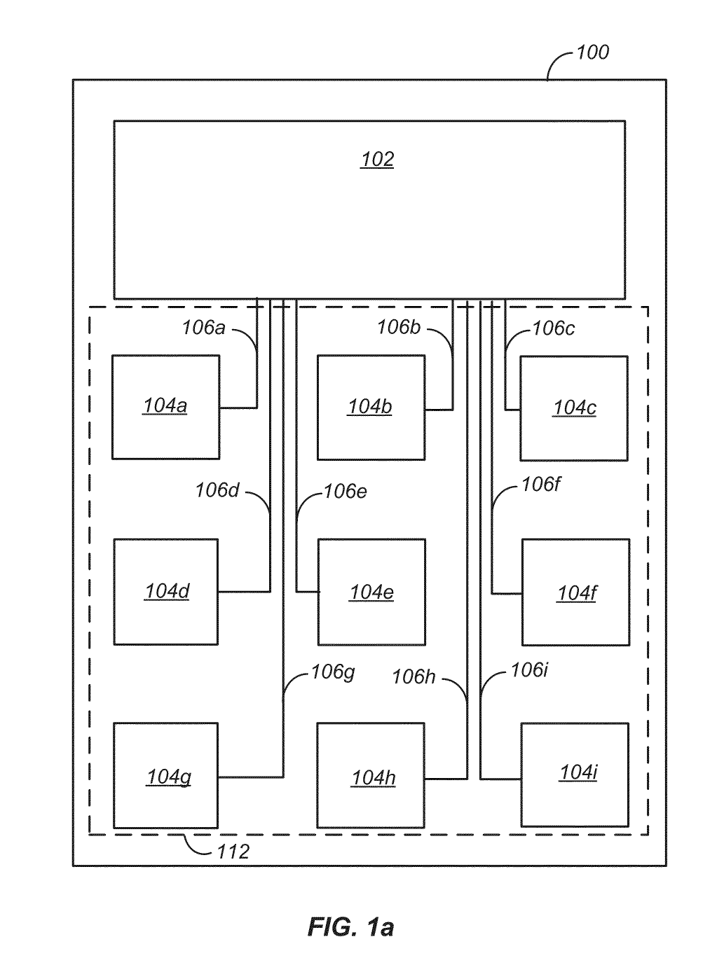

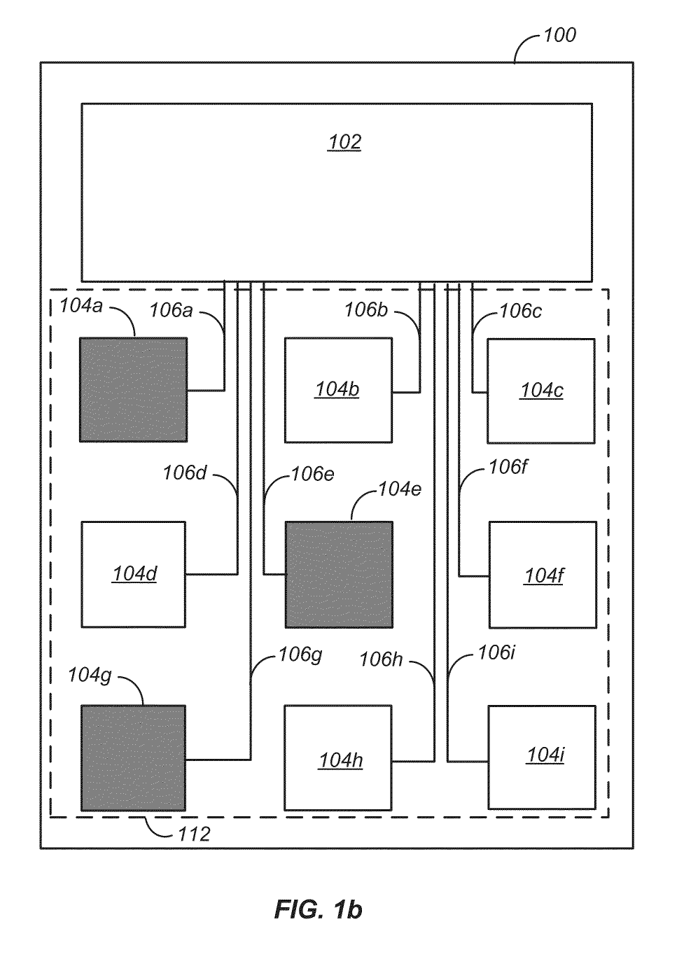

FIGS. 1a-1b are simplified diagrams of input forms that may be used to obtain electronic data in accordance with some embodiments of the invention. The input form 100 shown in FIG. 1a includes a wireless interface circuit (e.g., an RFID tag circuit 102) coupled to an electronic sensor 112. The RFID tag circuit 102 provides electronic data from the electronic sensor 112 to an RFID reader. The RFID tag circuit 102 may be active or passive and is not limited to a particular configuration. Although not specifically shown, the RFID tag circuit 102 may include at least an antenna and an integrated circuit. The antenna may be used for receiving and transmitting radio frequency (RF) signals, and the integrated circuit may be used for storing and processing information, modulating and demodulating RF signals, collecting power from reader signals, and other functions. In some embodiments, the RFID tag circuit 102 may include a battery for active or battery assisted passive operation.

The RFID tag circuit 102 shown in FIG. 1a is used merely as an example. In accordance with embodiments of the invention, any wireless interface circuit could be used to provide the electronic data from the electronic sensor 112 to a reader. This includes wireless interface circuis such as those defined by, but not limited to, standards organizations such as the International Organization for Standardization (ISO), the International Electrotechnical Commission (IEC), and the Institution of Electrical and Electronics Engineers (IEEE), including ISO/IEC/IEEE 8802-11, ISO/IEC/IEEE 8802-15, IEEE 802, and similar standards. Examples include WiFi, Bluetooth, and ZigBee.

The electronic sensor 112 is configured to sense a state based on physical manipulation of the input form 100 (or manipulation of the electronic sensor 112 on the input form 100). The electronic sensor 112 may include a number of sensors or sub-circuits each configured to sense a state that is changeable based on manipulation of a particular area of the input form 100. The state(s) of the electronic sensor 112 provide the electronic data. The electronic sensor 112 is also not limited to a particular configuration. In the example shown in FIG. 1a, the electronic sensor 112 includes a number of sub-circuits that each include connections 106a-106i and corresponding manipulation areas 104a-104i. While details of the electronic sensor 112 and each sub-circuit are not shown, it should be appreciated that each sub-circuit of the electronic sensor 112 may be configured in accordance with known techniques to sense at least a first state and a second state based on manipulation of each of the manipulation areas 104a-104i.

The manipulation changes a state of the electronic sensor 112 (or of the sub-circuits of the electronic sensor 112). The manipulation may also provide physical evidence of data creation in some embodiments. Merely by way of example, the electronic sensor 112 may be configured such that the minipulation includes filling in the manipulation areas 104a-104i, putting a check mark within or a line across the manipulation areas 104a-104i, punching a hole through the manipulation areas 104a-104i, etc. The manipulation may change a state of the electronic sensor 112 by changing an electrical characteristic of a circuit. For example, the manipulation may break or complete a trace, create a short or open in the circuit, or change a resistance, capacitance, or other characteristic of the circuit. The change may be permanent (e.g., by breaking a trace) or reversible (e.g., by bending the input form 100 to move two traces or capacitors closer together).

Merely by way of example, manipulation areas 104a, 104e, and 104g in FIG. 1b are each filled to change a state of the corresponding sub-circuits of the electronic sensor 112. Depending on the particular configuration, the manipulation areas 104a, 104e, and 104g may be filled using a conductive material (e.g., conductive ink) and/or a non-conductive material (e.g., non-conductive ink) to change a state of the sub-circuits.

An active RFID tag circuit 102 may include a battery and a memory configured to store changes in the state of the electronic sensor 112 as a history of the electronic data. In active operation, the electronic data may be provided to a reader near real-time, at specified intervals, upon occurrence of a specified event, upon interrogation by the reader, or the like. A passive RFID tag circuit 102 may provide a current state of the electronic sensor 112 as electronic data when interrogated by a reader using RF signals.

The RFID tag circuit 102 and the electronic sensor 112 may be coupled via an input/output (I/O) interface on the RFID tag circuit 102 in accordance with known techniques. The electronic sensor 112 may be coupled via a single interface or each sub-circuit of the electronic sensor 112 may be coupled via a separate interface.

The input form 100 provides a substrate on which the RFID tag circuit 102 and the electronic sensor 112 may be bonded or formed. The input form 100 may include paper, plastic, a textile, or the like. In some embodiments, the RFID tag circuit 102 and/or the electronic sensor 112 may be bonded to the input form 100 using, for example, an adhesive. In other embodiments, the RFID tag circuit 102 and/or the electronic sensor 112 may be formed on the input form 100 using, for example, a printing process using a conductive ink. Such printed electronic circuits may be formed in accordance with known techniques.

Connections 106a-106i and manipulation areas 104a-104i may be visible to a user as in the example shown in FIG. 1a, or they may be invisible to the user in other embodiments (e.g., covered with another layer or formed using transparent materials). The manipulation areas 104a-104i may be designated by traces of an electrical circuit or they may be designated by boxes, circles, or other objects and/or printing on the input form 100 that is not part of the electrical circuit.

The input form 100 may be used in a number of different applications to provide electronic data. The electronic data can be obtained using a reader that does not require contact with the input form 100 or the RFID tag circuit 102. Additionally, a reader can obtain the electronic data from a number of input forms 100 nearly simultaneously depending on a distance between the reader and each input form 100. This provides a number of benefits when the input form 100 is used, for example, as a ticket (e.g., bus or theatre), a label, a ballot, a test or survey answer sheet, an input sheet, or the like.

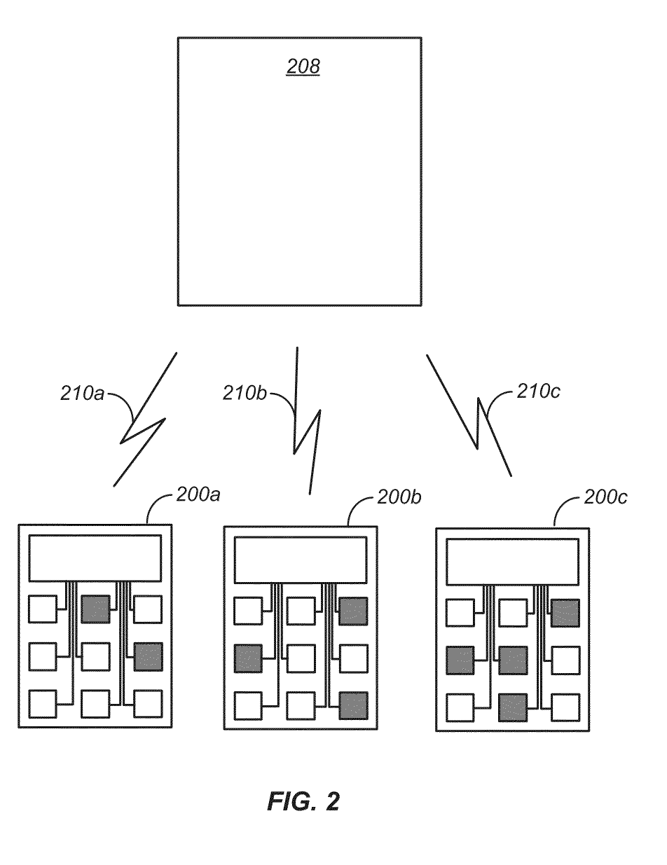

FIG. 2 is a simplified diagram of a system that may be used to obtain electronic data in accordance with an embodiment of the invention. The system includes a reader 208 and a number of input forms 200a, 200b, 200c. Each of the input forms 200a, 200b, 200c include a wireless interface circuit (such as an RFID tag circuit) and an electronic sensor. The wireless interface circuits and electronic sensors are shown on each of the input forms 200a, 200b, 200c in this example but are not separately identified by reference numerals. As can be seen, each of the input forms 200a, 200b, 200c include different electronic data based on manipulation of the different manipulation areas on each of the input forms 200a, 200b, 200c. The electronic data is transmitted wirelessly from each of the input forms 200a, 200b, 200c (or from the wireless interface circuits on each form) using signals 210a, 210b, 210c respectively.

As one example of a practical application, input forms in accordance with embodiments of the invention may be used as labels attached to boxes of freshly picked fruits or vegetables. Writing on each form may associate manipulation areas with a time and date the fruits or vegetables were picked (e.g., a manipulation area for each hour of the day, for each day of the month, and for each month of the year). The time and date may be selected by a worker in the field by manipulating the label (e.g., by filling in particular shapes, poking holes in particular areas, or the like depending on the particular configuration). Using a reader, the time and date the fruits or vegetables were picked can be determined remotely. Further, the time and date that each box of fruits or vegetables were picked in an entire shipment can be determined nearly simultaneously without having to visually inspect each box.

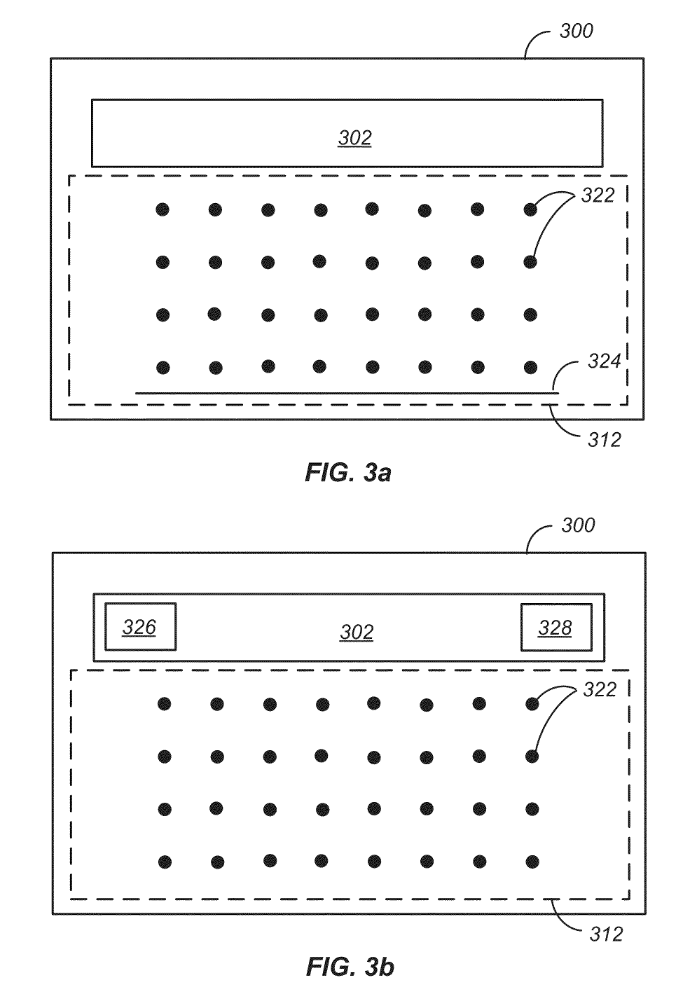

FIGS. 3a-3b are simplified diagrams of input forms that may be used to obtain electronic data in accordance with other embodiments of the invention. The input form 300 shown in FIG. 3a includes a wireless interface circuit (e.g., an RFID tag circuit 302) coupled to an electronic sensor 312. The wires or traces coupling the RFID tag circuit 302 to the electronic sensor 312 are not shown in this example. The input form 300, RFID tag circuit 302, and electronic sensor 312 may be configured in a manner similar to that of the input form 100, RFID tag circuit 102, and electronic sensor 112 shown in FIG. 1a and described above.

The electronic sensor 312 in this example includes a number of sensors 322 or sub-circuits each configured to sense a state that is changeable based on manipulation of a particular area of the input form 300. The sensors 322 may be visible or invisible to a user. In this example, the sensors 322 are arranged in a grid over a signature line 324. The signature line 324 may be part of the electronic sensor 312 or it may simply be a line printed on the form to indicate a manipulation area formed by the sensors 322. Some embodiments may include other shapes and/or configurations (e.g., a box) indicating the manipulation area instead of or in addition to the signature line 324.

In this example, manipulation of the form 300 may include a signature or other writing within the manipulation area. Density of the sensors 322 within the manipulation area may depend on the particular application and/or desired accuracy with which the writing is to be deciphered. The manipulation may leave a mark on the form 300 if done using a pen, pencil, or the like, or it may be done without marking the form 300 by using an instrument such as a stylus. Alternatively, an impact or chemical printing process may be used that manipulates the form or the electronic sensors. A state of the sensors 322 affected by the manipulation may be permanently altered (e.g., by breaking a trace, completing a circuit with a conductive ink, or the like) or only temporarily altered (e.g., by pressure).

The manipulation or writing may be deciphered by determining a state of each of the sensors 322 and knowing a position of each of the sensors 322 in the grid. In active operation, the RFID tag circuit 302 may provide a change in a state of the sensors 322 as electronic data to a reader. The electronic data may be provided near real-time or at specified intervals. As shown in FIG. 3b, in some embodiments the RFID tag circuit 302 may include a battery 326 and a memory 328 to store changes between states of the sensors 322. This may be used to store a history of the changes. The history may be provided to a reader at specified intervals, upon occurrence of a specified event, upon interrogation by a reader, or the like.

In passive operation, the RFID tag circuit 302 may provide a state of each of the sensors 322 upon interrogation by a reader. In some embodiments, a passive RFID tag circuit may be configured to count a number of times it is interrogated so that an incrementing counter can establish a sequential history of the state changes.

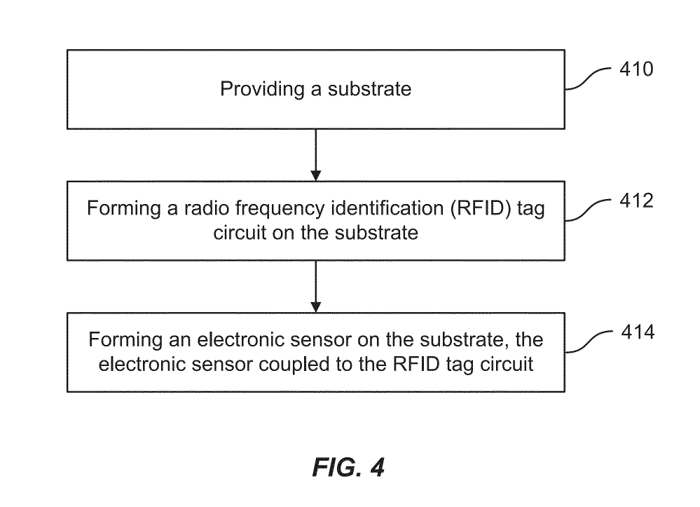

FIG. 4 is a flowchart of a method for forming an input form that is configured to provide electronic data in accordance with an embodiment of the invention. A substrate is provided (410) and an RFID tag circuit is formed on the substrate (412). The substrate may include paper, plastic, a textile, or the like. The RFID tag circuit may be bonded to the substrate using an adhesive or may be formed on the substrate using a printing process. An electronic sensor is formed on the substrate and coupled to the RFID tag circuit (414). The electronic sensor may be bonded to the substrate using an adhesive or may be formed on the substrate using a printing process. The electronic sensor may be configured to sense at least a first state and a second state based on manipulation of the substrate (or manipulation of the electronic sensor). The RFID tag circuit may be configured to provide the electronic data including a state of the electronic sensor to an RFID reader.

It should be appreciated that the specific steps illustrated in FIG. 4 provide a particular method for forming a form that is configured to provide electronic data in accordance with an embodiment of the present invention. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences. Furthermore, additional steps may be added or removed depending on the particular application.

Electronic sensors used in embodiments of the invention are not limited to configurations that sense physical manipulation of a form. Electronic sensors may also be used that are configured to sense environmental conditions (temperature, pressure, humidity, or the like), force (shock, impact, or the like), exposure to radiation, and the like. Electronic sensors may also be used that are configured to track internal events such as time. Some of these conditions may physically manipulate the electronic sensor without impacting the form.

In some embodiments, the RFID tag circuits may be configured to sense compound states (or a set of states from one or more electronic sensors that may or may not occur in a particular order). This allows the RFID tag circuits to act on state information to create new states that are not directly associated with the states of individual electronic sensors. A compound state may direct an RFID tag circuit, for example, to allow access to or modification of a memory. In an embodiment a passive RFID tag circuit under interrogation (powered by an RFID reader) may be configured to sense permanent or momentary state changes to create a compound state. Merely by way of example, the compound state may be associated with detection of an access code or password.

As described above, active RFID tag circuits allow for the detection and storage of momentary changes of state as a history of electronic data. In accordance with some embodiments, active RFID tag circuits may also allow for associating an input from a time keeping circuit with the state change. The time keeping circuit could be as simple as an incrementing counter or it could include a time and date.

While the present invention has been described in terms of specific embodiments, it should be apparent to those skilled in the art that the scope of the present invention is not limited to the embodiments described herein. For example, features of one or more embodiments of the invention may be combined with one or more features of other embodiments without departing from the scope of the invention. The specification and drawings are, accordingly, to be regarded in an illustrative rather than a restrictive sense. Thus, the scope of the present invention should be determined not with reference to the above description but with reference to the appended claims along with their full scope of equivalents.

What is claimed is:

1. A system for obtaining electronic data from a plurality of forms, comprising:
a plurality of electronic sensors, at least one electronic sensor coupled to each form, each electronic sensor configured to sense at least a first state and a second state based on manipulation of the form to which the electronic sensor is coupled;
a plurality of radio frequency identification (RFID) tag circuits, at least one of the RFID tag circuits coupled to each form and to the at least one electronic sensor coupled to the form; and
an RFID reader configured to communicate with the plurality of RFID tag circuits to obtain the electronic data from the plurality of forms, for each form the electronic data including at least one state of the at least one electronic sensor coupled to the form.

2. The system of claim 1 wherein the plurality of electronic sensors are printed electronic sensors comprising a conductive ink.

3. The system of claim 1 wherein the plurality of RFID tag circuits are printed RFID tag circuits comprising a conductive ink.

4. The system of claim 1 wherein at least one of the plurality of forms comprises paper.

5. The system of claim 1 wherein at least one of the plurality of forms comprises plastic.

6. The system of claim 1 wherein at least a portion of the RFID tag circuits are active RFID tag circuits that include a memory, each active RFID tag circuit configured to store in the memory changes between the first state and the second state sensed by the at least one electronic sensor.

7. The system of claim 1 wherein at least a portion of the RFID tag circuits are passive RFID tag circuits, and the RFID reader is configured to interrogate the passive RFID tag circuits using radio frequency (RF) signals to obtain the electronic data.

8. A form for providing electronic data comprising:
a substrate;
a wireless interface circuit coupled to the substrate;
at least one electronic sensor coupled to the substrate and to the wireless interface circuit, the electronic sensor configured to sense at least a first state and a second state based on manipulation of the substrate or manipulation of the electronic sensor, the wireless interface circuit configured to provide the electronic data including at least one state of the electronic sensor to a reader.

9. The form of claim 8 wherein the wireless interface circuit includes a radio frequency identification (RFID) tag circuit.

10. The form of claim 8 wherein the wireless interface circuit is based on at least one of an ISO/IEC/IEEE 8802-11, ISO/IEC/IEEE 8802-15, or IEEE 802 standard.

11. The form of claim 8 wherein the at least one electronic sensor is a printed electronic sensor comprising a conductive ink.

12. The form of claim 8 wherein the at least one electronic sensor comprises an electronic circuit that is bonded to the substrate.

13. The form of claim 8 wherein the wireless interface circuit is a printed wireless interface circuit comprising a conductive ink.

14. The form of claim 8 wherein the wireless interface circuit comprises an electronic circuit that is bonded to the substrate.

15. The form of claim 8 wherein the substrate comprises paper.

16. The form of claim 8 wherein the substrate comprises plastic.

17. The form of claim 8 wherein the wireless interface circuit is an active radio frequency identification (RFID) tag circuit that includes a memory, the active RFID tag circuit configured to store in the memory changes between the first state and the second state sensed by the electronic sensor.

18. The form of claim 8 wherein the wireless interface circuit is a passive radio frequency identification (RFID) tag circuit, the passive RFID tag circuit configured to provide the state of the electronic sensor to an RFID reader upon interrogation by the RFID reader using radio frequency (RF) signals.

19. A method for forming a form that is configured to provide electronic data, the method comprising:
providing a substrate;
forming a radio frequency identification (RFID) tag circuit on the substrate;
forming an electronic sensor on the substrate, wherein the electronic sensor is coupled to the RFID tag circuit, the electronic sensor configured to sense at least a first state and a second state based on manipulation of the substrate, the RFID tag circuit configured to provide the electronic data including a state of the electronic sensor to an RFID reader.

20. The method of claim 19 wherein the RFID tag circuit is formed using a conductive ink that is applied to the substrate using a printing process.

21. The method of claim 19 wherein the electronic sensor is formed using a conductive ink that is applied to the substrate using a printing process.

22. The method of claim 19 wherein the substrate comprises paper.

23. The method of claim 19 wherein the substrate comprises plastic.

24. The method of claim 19 wherein the RFID tag circuit is an active RFID tag circuit that includes a memory, the active RFID tag circuit configured to store in the memory changes between the first state and the second state sensed by the electronic sensor.

25. The method of claim 19 wherein the RFID tag circuit is a passive RFID tag circuit, the passive RFID tag circuit configured to provide the state of the electronic sensor to an RFID reader upon interrogation by the RFID reader using radio frequency (RF) signals.
